(19) United States
(12) Patent Application Publication
(10) Pub. No.: US 2013/0068294 A1
(43) Pub. Date: Mar. 21, 2013

(54) DYE-SENSITISED SOLAR CELL WITH NICKEL CATHODE

(71) Applicants: Noel Clark, Victoria (AU); Matthias Hilder, Victoria (AU); Douglas Macfarlane, Victoria (AU); Jenny Pringle, Victoria (AU); Jyothi Ramamurthy, Victoria (AU); Bjorn Winther-Jensen, Victoria (AU)

(72) Inventors: Noel Clark, Victoria (AU); Matthias Hilder, Victoria (AU); Douglas Macfarlane, Victoria (AU); Jenny Pringle, Victoria (AU); Jyothi Ramamurthy, Victoria (AU); Bjorn Winther-Jensen, Victoria (AU)

(73) Assignees: Commwealth Scientific and Industrial Reseach Organisation; Securency International Pty Limited; Monash University; The University of Melboune

(21) Appl. No.: 13/637,353

(22) PCT Filed: Apr. 1, 2011
(86) PCT No.: PCT/AU11/00383

§ 371 Date: Dec. 3, 2012

(30) Foreign Application Priority Data
Apr. 1, 2010 (AU) 2010901417

(51) Int. Cl. H01L 31/0224; H01L 31/18; H01L 51/44

(52) U.S. Cl. 136/256; 136/263; 438/98; 438/62; 257/E31.124

(57) ABSTRACT

The present invention relates to a cathode for use in a dye-sensitised solar cell which comprises a redox couple, wherein the cathode comprises: (a) metallic nickel; and (b) intrinsically conducting polymer that, during operation of the cell, reduces an oxidised species of the redox couple.

### FIELD OF THE INVENTION

The present invention relates generally to dye-sensitised solar cells. In particular, the invention relates to a cathode for use in dye-sensitised solar cells, to the dye-sensitised solar cells comprising the cathode, and to methods for manufacturing the same.

### BACKGROUND OF THE INVENTION

In recent years there has been considerable research directed toward developing alternative energy sources to conventional fossil fuels. Photovoltaic systems have proven to be particularly promising in that regard.

In general terms, photovoltaic systems are implemented to convert light energy to electricity for a variety of applications. Photovoltaic systems are commonly referred to as “solar cells”, so named due to their ability to produce electricity from sunlight.

A variety of solar cells have been developed to date. Of these, silicon based solar cells have proven to be the most commercially viable option.

However, silicon solar cells are renowned for being expensive to manufacture. Furthermore, there is some limitations in the practical application and improvement in the efficiency of such cells.

Dye-sensitised solar cells (DSSC's) have been found to exhibit a number of advantages over conventional silicon based solar cells. For example, they can be manufactured using relatively low-cost materials and relatively simple apparatus/infrastructure.

Unlike silicon based solar cells, DSSC's operate through a photoelectrochemical process, with the first of such cells being only recently reported by Gratzel et al in 1991.

A schematic illustration of the principal of operation of a DSSC is shown in FIG. 1. Thus, photons (1), typically from sunlight, pass through a transparent anode (5) and promote photo-excitation of a photosensitive dye (20) depicted by the transition of D to D*. This photo-excitation of the dye results in the injection of an electron into a semi-conductor (10) such as titanium dioxide or zinc oxide. In practice, the semi-conductor (10) is generally in the form of a nanocrystalline solid onto which the photosensitive dye (20) is adsorbed. Electrons injected into the semi-conductor (10) can then move by diffusion and collect at the transparent anode (5) where, as a result of a potential difference between the transparent anode (5) and the cathode (40) (also known in the art as the counter electrode), the electrons can flow in the direction of the cathode (40) through a load (45) such as a light globe located in the circuit. Having injected an electron into the semi-conductor (10), the photosensitive dye (20) becomes unstable, but is restored to its original state by receiving an electron from the reduced species of the redox couple (30) present within the electrolyte composition (25). As a result of the electron transfer from the reduced species of the redox couple (30) to the photosensitive dye (20), the reduced species is in effect oxidised to become the oxidised species of the redox couple (30). The now oxidised species of the redox couple (30) is then reduced at the cathode (40) to complete the cell circuit and in turn again function as the reduced species of the redox couple (30) that can transfer an electron to the photosensitive dye (20). A common redox couple (30) used in DSSC's is the I₃⁻/3I⁻ couple (i.e. triiodide/iodide couple).

An important feature of DSSC's is that the cathode provides a surface that can reduce the oxidised species of the redox couple. The property of the cathode that enables it to reduce the oxidised species of the redox couple is sometimes referred to in the art as its catalytic activity. A common material used in the manufacture of cathodes for DSSC's that exhibits both the required conductivity and catalytic activity is platinum. Due to the high cost of platinum, the cathodes are generally constructed in a manner that minimises the amount of platinum used. For example, DSSC's typically employ cathodes constructed of a conductive layer of indium tin oxide (ITO) or fluorine tin oxide (FTO) on a glass substrate, where a thin layer of platinum is applied onto the surface of the oxide layer.

Despite attempts to minimise the use of expensive materials such as platinum, the cost of materials used in the manufacture of conventional cathodes for DSSC's can amount to as much as 60% of the total manufacturing cost of the cell.

Accordingly, there remains an opportunity to develop technology for at least reducing the cost of manufacturing DSSC's, or simply to develop technology for producing alternative DSSC systems.

### SUMMARY OF THE INVENTION

The present invention therefore provides a cathode for use in a dye-sensitised solar cell which comprises a redox couple, wherein the cathode comprises:
(a) metallic nickel; and
(b) intrinsically conducting polymer that, during operation of the cell, reduces an oxidised species of the redox couple.

The present invention also provides a cathode when used in a dye-sensitised solar cell which comprises a redox couple, wherein the cathode comprises:
(a) metallic nickel; and
(b) intrinsically conducting polymer that, during operation of the cell, reduces an oxidised species of the redox couple.

The present invention further provides a method of manufacturing a cathode for use in a dye-sensitised solar cell which comprises a redox couple, the method comprising constructing the cathode using:
(a) metallic nickel; and
(b) intrinsically conducting polymer that, during operation of the cell, reduces an oxidised species of the redox couple.

The present invention also provides a dye-sensitised solar cell comprising a cathode and a redox couple, wherein the cathode comprises:
(a) metallic nickel; and
(b) intrinsically conducting polymer that, during operation of the cell, reduces an oxidised species of the redox couple.

The present invention further provides a method of manufacturing a dye-sensitised solar cell, the dye-sensitised solar cell comprising a cathode and a redox couple, the method comprising constructing the cathode using:
(a) metallic nickel; and
(b) intrinsically conducting polymer that, during operation of the cell, reduces an oxidised species of the redox couple.

The present invention also provides a method of manufacturing a dye-sensitised solar cell, the dye-sensitised solar cell comprising a cathode and a redox couple, the method comprising constructing the dye-sensitised solar cell using a cathode in accordance with the invention.

It has now been found that metallic nickel may be used in combination with an intrinsically conducting polymer (ICP) to construct a cathode for use in DSSC's. Without wishing to be limited by theory, it is believed that the nickel promotes good conductivity of the cathode, whereas the ICP promotes conductivity of the cathode and also functions as a catalyst during operation of the cell to reduce oxidised species of the redox couple.

DSSC's made using a cathode according to the invention have been shown to exhibit a conversion efficiency approaching that of similar cells using conventional ITO/platinum cathodes. Most notably, DSSC's according to the present invention can be manufactured at considerably lower cost than that of conventional DSSC's.

The intrinsically conducting polymer and the metallic nickel may be spatially arranged within the cathode in various ways. Nevertheless, the cathode will generally include a layer comprising the metallic nickel, and that layer will typically comprise a relatively high proportion (e.g. at least 50 wt %, for example at least 65 wt %, at least 75 wt %, at least 85 wt %, or at least 95 wt %) of the metallic nickel relative to any other metal(s) if present. The ICP may be interspersed within the layer comprising the metallic nickel, or it may be present in a separate layer.

In one embodiment of the invention, the intrinsically conducting polymer is interspersed with the metallic nickel so as to form a composite blend of the intrinsically conducting polymer and the metallic nickel. The cathode will typically comprise a layer of such a composite blend.

In a further embodiment of the invention, a layer comprising the intrinsically conducting polymer is located upon a layer comprising the metallic nickel.

In one embodiment of the invention, a layer comprising the intrinsically conducting polymer consists essentially of the intrinsically conducting polymer.

In a further embodiment of the invention, a layer comprising the metallic nickel consists essentially of the metallic nickel.

In yet a further embodiment of the invention, a layer comprising the metallic nickel comprises the intrinsically conducting polymer.

In another embodiment of the invention, a layer comprising the intrinsically conducting polymer includes one or more further materials.

In a further embodiment of the invention, a layer comprising the metallic nickel includes one or more further materials.

Where the intrinsically conducting polymer is interspersed with the metallic nickel so as to form a composite blend, the cathode may be constructed using a dispersion comprising the metallic nickel and the intrinsically conducting polymer. For example, the metallic nickel and the intrinsically conducting polymer may be provided in the form of a dispersion (collectively in one dispersion, or as individual dispersions and each dispersion combined) and the cathode constructed by applying the dispersion onto a substrate.

Where a layer comprising the intrinsically conducting polymer is located upon a layer comprising the metallic nickel, the layer comprising the metallic nickel may be prepared using a dispersion of the metal(s), a metal foil, and/or using a metal deposition technique such as electroplating, evaporation, vacuum sputtering, and electroless plating.

Where a layer comprising the intrinsically conducting polymer is located upon a layer comprising the metallic nickel, the layer comprising the intrinsically conducting polymer may be formed using a dispersion comprising the intrinsically conducting polymer, and/or by using an electrochemical or chemical oxidative polymerisation technique. Where a chemical oxidative polymerisation technique is used, it may be selected from bulk or vapour phase polymerisation.

In one embodiment according to the methods of the invention, a layer comprising the intrinsically conducting polymer is formed upon a layer comprising the metallic nickel; wherein the layer comprising the metallic nickel is formed using a dispersion comprising the metallic nickel, and wherein the layer comprising the intrinsically conducting polymer is formed by vapour phase polymerisation.

In one embodiment of the invention, the cathode further comprises, or is formed on, a substrate.

In another embodiment of the invention, the substrate is a polymer.

In a further embodiment of the invention, the substrate is a flexible material suitable for use in roll-to-roll processing.

In another embodiment of the invention, the substrate is a flexible polymer suitable for use in roll-to-roll printing applications.

Further features of the invention are discussed below in the detailed description of the invention.

### BRIEF DESCRIPTION OF THE DRAWINGS

Preferred embodiments of the invention will now be illustrated by way of example only with reference to the accompanying drawings in which:

FIG. 1 illustrates a schematic of the principal operation of a dye-sensitised solar cell. When describing the present invention with reference to this Figure, the cathode (40) of the cell is intended to be a cathode according to the present invention and not a conventional cathode according to the prior art.

FIG. 2 illustrates a schematic of the polished nickel coating profile.

FIG. 3 illustrates Quartz crystal cyclic voltammetry scan 1.

FIG. 4 illustrates Quartz crystal cyclic voltammetry scan

FIG. 5 illustrates 1 layer of PEDOT/PTS, position 1.

FIG. 6 illustrates 2 layers of PEDOT/PTS, position 1.

FIG. 7 illustrates 3 layers of PEDOT/PTS, position 1.

FIG. 8 illustrates a cyclic voltammetry scan of glass/FTO/platinum symmetric cell.

FIG. 9 illustrates a cyclic voltammetry scan of PET/nickel/PEDOT:PTS symmetric cell.

FIG. 10 illustrates a gradient graph of glass/FTO/Pt symmetric cell (1).

FIG. 11 illustrates a gradient graph of glass/FTO/Pt symmetric cell (2).

FIG. 12 illustrates a gradient graph of PET/Ni/PEDOT:PTS symmetric cell (1).

FIG. 13 illustrates a gradient graph of PET/Ni/PEDOT:PTS symmetric cell (2).

FIG. 14 demonstrates the correlation between gradient of the graph and the mass of PEDOT:PTS printed on each electrode.

FIG. 15 illustrates a typical electrical impedance scan.

### DETAILED DESCRIPTION OF THE INVENTION

Those skilled in the art will appreciate that a DSSC comprises both an anode and a cathode. In the context of DSSC's, the cathode may also be referred to in the art as a “counter electrode”.

In its simplest form, the cathode in accordance with the invention may be constructed primarily from metallic nickel, and an ICP.

The cathode may, and generally will, comprise one or more further materials. For example, and as will be discussed in more detail below, the cathode may further comprise a binder, and/or the cathode may be provided on a substrate. In practice, a substrate will typically be used to impart structural support to the cathode.

When used, a substrate may be electrically conductive or electrically non-conductive (i.e. an insulator). Where the substrate is electrically conductive, it may function as part of the cathode per se. Where the substrate is electrically non-conductive, then strictly speaking the substrate is not part of the cathode per se. Having said this, it is not uncommon for a person skilled in the art to refer to a cathode provided on a substrate as “the cathode” irrespective of whether or not the substrate is electrically conductive or not. Examples of materials from which a substrate may be formed include glass, ceramic, polymer, metal or combinations thereof.

In one embodiment, the substrate is a flexible material suitable for use in roll-to-roll processing applications. By utilising such a substrate, one or more steps in the manufacture of the cathodes can advantageously be performed using roll-to-roll processing.

Roll-to-roll processing, also known as web processing, reel-to-reel processing or R2R, is a process for manufacturing electronic devices on a roll of flexible plastic or metal foil. In such processing, the flexibility required of the substrate is normally governed by a need to bend at least 90° and up to 180° around rollers of diameter down to 50 mm without becoming unduly damaged.

Roll-to-roll processing can advantageously achieve a compact web path whilst still allowing sufficient time for an applied coating(s) to dry or solidify before subsequent processing or rewinding.

The substrate can vary in width from a few centimetres to metres, although high value products based on expensive raw materials such as solar cells tend to favour smaller widths, typically in the 300-330 mm range.

The substrates may be patterned during roll-to-roll processing by various techniques that include photolithography, inkjet, gravure, reverse gravure, slot die or screen printing. Such processing is often referred to as roll-to-roll printing. In the context of the present invention the objective is to apply functional coatings (e.g. coatings that give rise to the cathode), which typically requires strict quality standards relating to printed film thickness, uniformity and continuity.

Examples of polymer materials that may be used as a substrate include flexible polymers suitable for roll-to-roll printing such as polyethylene terephthalate (PET) or polyethylene naphthalate (PEN) films.

As will be discussed in more detail below, the DSSC's according to the present invention are of a type that comprises a redox couple. Those skilled in the art will therefore appreciate that cathodes according to the invention are constructed so as to have the required conductivity and catalytic activity to operate in such cells.

A cathode in accordance with the invention will generally include a layer comprising the metallic nickel. Accordingly, the cathode may be described as comprising or being constructed using:
(a) a layer comprising metallic nickel; and
(b) intrinsically conducting polymer that, during operation of the cell, reduces an oxidised species of the redox couple.

The layer comprising the metallic nickel may include or be separate from the ICP. Nevertheless, this layer will typically comprise a relatively high proportion (e.g. at least 50 wt %, for example at least 65 wt %, at least 75 wt %, at least 85 wt %, or at least 95 wt %) of the metallic nickel, relative to any other metal(s) if present.

Generally, the layer comprising the metallic nickel will comprise the ICP or will be directly adjacent to a layer comprising the ICP.

Those skilled in the art will appreciate that redox couples used in DSSC's can be highly corrosive. The cathode in accordance with the invention has advantageously been found to be resistant to the corrosive nature of such redox couples. Without wishing to be limited by theory, the metallic nickel content of the cathodes is believed to facilitate with imparting such corrosion resistance properties.

As noted above, the ICP and the metallic nickel may be spatially arranged within the cathode in various ways.

Where the ICP is interspersed with the metallic nickel so as to form a composite blend structure or layer, the nickel will generally be present in that composite blend structure or layer in an amount of at least 50 wt %, for example at least 65 wt %, at least 75 wt %, at least 85 wt %, or at least 95 wt %, relative to the total weight of metal in that composite blend structure or layer.

Where a layer comprising the ICP is located upon a layer comprising the metallic nickel the layer comprising the metallic nickel will generally comprise the nickel in an amount of at least 50 wt %, for example at least 65 wt %, at least 75 wt %, at least 85 wt %, or at least 95 wt %, relative to the total weight of metal in that layer.

The metallic nickel may be present in the cathode in a variety of physical forms.

Where more than one of these metals is present, they may be in the form of an alloy or as a simple mixture with one or both of the other metals. The nickel may also be present as an alloy or simple mixture with one or more further metals.

The metallic nickel (or alloy thereof) may be provided in the form of divided particles such as flakes, or in the form of a continuous sheet or film.

Where the metallic nickel is in the form of divided particles, the particles will generally be dispersed within a binder. The binder may be an organic binder such as a polymer binder. For example, and as will be discussed in more detail below, the cathode may be constructed using a dispersion of the metallic nickel in particulate form and a polymer binder in a liquid. Upon evaporation of the liquid, the polymer binder functions to retain the nickel particles as an integral mass.

In other words, the metallic nickel may be provided in the form of particles dispersed within a polymer matrix. Where the polymer matrix is not of itself conductive, the nickel particles will of course have sufficient connectivity and/or concentration within the polymer matrix to enable current to flow therethrough.

In addition to the binder, a dispersion of the metallic nickel may also comprise one or more further materials such as additives. The additives may be used to enhance conductivity of the resulting metal/binder composite (e.g. an electrical bridging additive such as carbon), and/or to modify the physical properties (e.g. surface or mechanical properties) of the resulting metal/binder composite.

Techniques, equipment and reagents known in the art can advantageously be used for preparing metallic nickel dispersed within a binder.

For example, the art of preparing liquid dispersions of polymer binder and metal particles is known in the coatings industry and can advantageously be applied in preparing metallic nickel dispersions that may be used in accordance with the invention. Thus, the dispersions may be prepared using metallic nickel and/or alloy particles thereof, polymer binder such as an acrylic resin and a liquid such as an organic or aqueous solvent. To maintain the particles and polymer binder in a dispersed state within the liquid, the dispersion will generally also comprise a surfactant.

Dispersions of the metallic nickel used in accordance with the invention may be obtained commercially. For example, nickel/polymer binder dispersions may be obtained from MG Chemicals, Canada in formulations suitable for application by spray or paint applicator.

When in the form of a dispersion (together with binder), it will be appreciated that the metallic nickel will be present in an amount that gives rise to suitable conductivity of the cathode. The dispersion may comprise one or more additives that assist with imparting the required electrical conductivity.

A dispersion comprising polymer binder and the metallic nickel may, for example, comprise the one or metals in an amount ranging from about 15 wt % to about 50 wt %, relative to the weight of the dispersion.

Where the metallic nickel is in the form of a continuous sheet or film, the sheet or film will generally be derived from a foil of the appropriate metal(s) and/or using a metal depositing technique such as electroplating, evaporation, vacuum sputtering, and electroless plating.

Depending upon how the cathode in accordance with the invention is constructed, the metallic nickel may be interspersed with other components of the cathode (e.g. when derived from a dispersion), or may present as a discreet continuous metal layer of the cathode (e.g. as a continuous sheet or film of metal).

By being “interspersed” is meant that relevant components are intermixed so as to form a blend composition having the components distributed throughout the blend.

The cathode in accordance with the invention also comprises an ICP. As used herein, an “ICP” or “intrinsically conducting polymer” is intended to mean a polymer that has a molecular structure through which electrical current can flow. Such a polymer is to be distinguished from a polymer composite comprising a conductive material such as metal where conduction of the electrical current occurs via the conductive material contained therein and not the polymer per se.

ICP's are typically organic polymers having an extended conjugated π-electron system. All polymers having an extended conjugated system may not inherently present as an ICP suitable for use in accordance with the invention. Those skilled in the art will appreciate that conductivity of polymers having extended conjugated systems may be promoted or increased through doping (i.e. the introduction of charge to the conjugated system for example by (a) electron removal (oxidation or p-doping), (b) electron injection (reduction or n-doping), or (c) protonation (acid doping)). For example, polyaniline can exist in numerous valence states such as a reduced state (laucoeneraldine), a partially oxidised state (emeraldine) and a fully oxidised state (pernigraniline). Polyaniline is the most conductive in its emeraldine form (+2 electrons). This partially oxidised state of polyaniline can be readily formed through doping.

An ICP used in accordance with the invention is of a type that, during operation of the DSSC, will conduct sufficient electricity for the DSSC to function.

The majority of known polymers having extended conjugated systems are built up from electron rich monomer units and as such are particularly amenable to p-doping. ICP's used in accordance with the invention will generally be p-doped. Examples of suitable anionic dopants include, but are not limited to, chloride, dodecylbenzenesulfonate, per chlorate, tetrofluoroborate, sulfate, sulfonate, oxylate, sulfosalicylate, nitrate, fluoromethyl sulfonate, p-toluenesulfonate or combinations thereof.

In one embodiment, the ICP used in accordance with the invention is p-doped. In that case, a suitable doping anion may be selected from those defined herein.

In addition to being electrically conductive, the ICP used in accordance with the invention must also be of a type that, during operation of the DSSC, reduces an oxidised species of the redox couple in the cell. In particular, DSSC's in accordance with the invention are of a type that comprises a redox couple. As previously discussed, redox couples are commonly used in conventional DSSC's and primarily function to reduce the oxidised form of the photosensitive dye which results from, or is formed by, the dye injecting electrons into the semi-conductor of the cell upon undergoing photo-excitation. More specifically, a redox couple will typically comprise a combination of a reduced and an oxidised form of a particular ion or neutral species. The reduced form of the couple undergoes oxidation by transfer of an electron to an oxidised form of the photosensitive dye to yield the oxidised form of the couple, and the oxidised form of the couple undergoes reduction upon receiving electrons from the cathode of the cell to yield the reduced form of the couple. During operation of the cell, the redox species can therefore cycle through their reduced and oxidised forms to provide the redox couple.

By the ICP being of a type that “reduces an oxidised species of the redox couple” is therefore meant that as part of the cathode the ICP functions to promote electron transfer to an oxidised form of the redox couple to yield the reduced form of the couple.

The properties of a given material that enable it to function as a catalyst in a DSSC and promote such a reduction reaction at the cathode are not yet well understood. Nevertheless, the property of a given ICP to function in this way can be readily assessed by a person skilled in the art. For example, the ICP needs to be oxidized or partially oxidized at the potential at which the electrolyte redox species is reduced in the DSSC environment and this can be readily established by conventional Cyclic Voltammetry tests.

Provided that the ICP used in the DSSC can function as a catalyst for the redox couple, there is no particular limitation concerning the type of redox couple that may be used as part of the DSSC in accordance with the invention. For example, the redox couple may be selected from iodine, bromine, ferrocene, cobalt or TEMPO (2,2,6,6-Tetramethylpiperidine-1-oxyl). A TEMPO redox couple affords a radical anion that can be reduced by an ICP such as poly(3,4-ethylenedioxythiophene) but not by platinum.

In one embodiment, the redox couple used in accordance with the invention is a triiodide/iodide couple.

Where a triiodide/iodide redox couple is used in accordance with the invention, it may be derived from reagents well known to those skilled in the art. For example, the triiodide/iodide redox couple may be obtained by mixing molecular iodine (I₂) with, for example, an iodide of an alkali metal or an alkaline earth metal or an iodine salt of an organic cation.

More specific examples of suitable iodide species include, Li, Na, K, and Mg iodides, a quaternary ammonium compound such as tetraalkylammonium iodine salt, pyridinium iodine salt and imidazolium iodine salt, and an iodide of a heterocyclic nitrogen-containing compound such as 1,3-dimethyl imidazolium iodide, 1-methyl-3-ethyl imidazolium iodide, 1-methyl-3-propyl imidazolium iodide, 1-methyl-3-hexyl imidazolium iodide, 1,2-dimethyl-3-propyl imidazole iodide, 1-ethyl-3-isopropyl imidazolium iodide, and pyrrolidinium iodide. One or more selected from these compounds can be used.

The expression “redox couple” used herein is intended to encompass the situation where all or substantially all of the redox couple is present in its oxidised or reduced form at some point in time, as well as the situation where some of the redox couple is present in the oxidised form and the remainder is present in the reduced form. Nevertheless, those skilled in the art will appreciate that during operation of the cell, both oxidised and reduced forms of the redox couple will generally be present.

The redox couple used in a DSSC in accordance with the invention will typically form part of an electrolyte composition. The electrolyte composition facilitates the transfer of electrical current within the cell.

The electrolyte composition will comprise the redox couple and generally one or more components selected from an organic solvent, ionic liquid or mixtures thereof.

An example of an organic solvent that may form part of the electrolyte composition includes acetonitrile.

An example of an ionic liquid that may be used includes those based on thiocyanates such as 1-ethyl-3-methylimidazolium thiocyanate.

In one embodiment, the electrolyte composition comprises acetonitrile/valeronitrile (85:15 vol %), iodine (0.03 M), 4-tertbutylpyridine (0.5 M), 1-butyl-3-methylimidazolium iodide (0.6 M) and guanidinium thiocyanate (0.1 M).

In another embodiment, the electrolyte composition comprises 1-ethyl-3-methylimidazolium tetracyanoborate, 1-ethyl-3-methylimidazolium iodide, dimethylimidazolium iodide, guanidinium thiocyanate, iodine, N-methylbenzimidazole at a molar ratio of 16:12:12:1:1.67:4.

Where the cathode in accordance with the invention is formed using a dispersion of metallic nickel comprising polymer, it may be desirable to select an electrolyte composition based on an ionic liquid system, or an organic solvent system where the solvent does not adversely effect the durability of the nickel/polymer composition. In particular, certain organic solvents may cause the polymer binder component of a nickel/polymer dispersion to become damaged (e.g. soften, swell etc) and reduce the efficiency and/or durability of the cathode.

There is no particular limitation concerning the type of ICP that may be used in accordance with the invention provided it exhibits the required conductivity and catalytic activity to function in the DSSC.

Examples of suitable ICP's that may be used in accordance with the invention include those formed by the polymerisation of one or more optionally substituted aromatic monomer compounds. Examples of suitable optionally substituted aromatic monomer compounds include optionally substituted aryl such as aniline, and optionally substituted aromatic heterocyclic compounds such as optionally substituted 5-membered aromatic heterocyclic compounds. In the case of optionally substituted 5-membered aromatic heterocyclic compounds, those skilled in the art will appreciate that only the β,β′ positions of the 5-membered rings can be substituted so as to allow for coupling of the monomers and subsequent formation of the polymer chain through the α,α′ positions.

In one embodiment, the ICP used in accordance with the invention comprises a polymerised residue of an optionally substituted aromatic compound selected from optionally substituted pyrrole (including N-substituted pyrrole), optionally substituted thiophene, optionally substituted aniline, optionally substituted furan, optionally substituted pyridine, optionally substituted indole, and optionally substituted carbazole.

In one embodiment, the optionally substituted aromatic monomer compound is a 5-membered aromatic heterocyclic monomer compound selected from those of general formula (I):

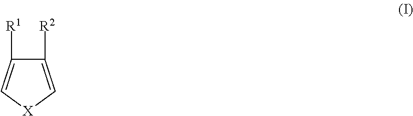

where R¹ and R² are each independently selected from hydrogen, optionally substituted alkyl, optionally substituted aryl, optionally substituted arylalkyl, or together form an optionally substituted cyclic substituent, and X is selected from O, S, and NR³, where R³ is selected from hydrogen, optionally substituted alkyl, optionally substituted aryl, and optionally substituted arylalkyl.

In one embodiment, R¹ and R² of formula (I) are each independently selected from hydrogen, optionally substituted C₁-C₈ alkyl, optionally substituted C₆-C₁₈ aryl, optionally substituted C₇-C₁₈ arylalkyl, or form together an optionally substituted C₂-C₁₀ cyclic substituent.

In one embodiment, R³ of formula (I) is selected from hydrogen, optionally substituted C₁-C₈ alkyl, optionally substituted C₆-C₁₈ aryl, and optionally substituted C₇-C₁₈ arylalkyl.

By R¹ and R² of formula (I) forming together a “cyclic substituent” is meant that together with the β,β′-carbon atoms of general formula (I) R¹ and R² form a ring or cyclic structure. The resulting cyclic substituent or carbocyclyl group may be a C₂₋₂₀ (e.g. C₂₋₁₀ or C₂₋₆) cyclic substituent. One or more of the carbon atoms in the cyclic substituent may be replaced by a heteroatom. Suitable heteroatoms include O, N, S, P and Se, particularly O, N and S. Where two or more carbon atoms are replaced, this may be by two or more of the same or different heteroatoms. Where one or more carbon atom of the cyclic substituent is replaced by a heteroatom, the substituent may be conveniently referred to as a heterocyclic substituent or a heterocyclyl group.

In one embodiment, the ICP used in accordance with the invention comprises the polymerised residue of an optionally substituted aromatic compound selected from optionally substituted pyrrole (including N-substituted pyrrole), and optionally substituted thiophene. Specific examples of optionally substituted thiophene include 3,4-ethylenedioxythiophene and 3,4-propylenendioxythiophene.

An ICP used in accordance with the invention may be a homopolymer or a copolymer.

Examples of specific ICP's that may be used in accordance with the invention include poly(optionally substituted pyrrole), poly(optionally substituted thiophene), poly(optionally substituted aniline), poly(optionally substituted furan), poly(optionally substituted pyridine), poly(optionally substituted indole), and poly(optionally substituted carbazole).

In one embodiment of the invention the ICP is a poly(optionally substituted thiophene) such as poly(3,4-ethylenedioxythiophene) (PEDOT) and poly(3,4-propylenedioxythiophene) (PRODOT).

The ICP used in accordance with the invention may comprise one or more other polymers that, in its own right; is not an ICP. For example, a poly(optionally substituted thiophene) such as poly(3,4-ethylenedioxythiophene) (PEDOT) is commonly prepared and used in the form of a mixture of PEDOT and polystyrene sulfonate (PSS). In that case, the sulfonate groups of the PSS function as a dopant for the PDOT. PEDOT:PSS is often prepared and used in the form of a dispersion of the polymer blend in a liquid.

To improve the conductivity of the ICP, non-ionic additives or so-called secondary dopants may also be used. These secondary dopants will typically be added after the ICP has been prepared but before the ICP is used in preparing the cathode, and include polyalcohols such as sorbitol and glycerol, polyethylene glycol or polar solvents such as dimethylsulfoxide, tetrahydrofuran or dimethylformamide.

An ICP used in accordance with the invention may be prepared using polymerisation techniques, equipment and reagents well known to those skilled in the art.

Suitable polymerisation techniques include cationic, radical, coordination, chemical oxidation, step growth and electrochemical polymerisation techniques.

The polymerisation technique employed will often be determined by the manner in which the cathode in accordance with the invention is to be constructed.

ICP's comprising a dopant will generally be prepared by polymerising the selected monomers in the presence of a suitable dopant.

Polymerisation techniques for preparing ICP's can broadly be categorised into chemical or electrochemical techniques.

Where an electrochemical polymerisation technique is employed, monomer is typically electrochemically oxidised to form the polymer on the surface of an anode that forms part of an electrochemical cell. The anode will generally form all or part of the substrate on to which the polymer is to be applied. Where such a technique is to be used in preparing an ICP that forms part of the cathode in accordance with the invention, it will be appreciated that the metallic nickel of the cathode will be provided in a form (as a conductive layer) that can function as an anode during the polymerisation.

Other compounds that will typically be present during electrochemical polymerisation include the ICP dopant and an acid added to provide a suitable pH for the reaction, as well as a suitable solvent that may be organic, aqueous or ionic in nature. The polymerisation itself may be carried out at constant voltage, at constant current, or under cyclic voltammetry, during which the electrical conditions may be systematically varied.

Chemical polymerisation techniques are often also referred to as chemical oxidative polymerisation techniques. By “chemical polymerisation” or “chemical oxidative polymerisation” is meant that monomer is oxidised by a chemical oxidant to afford a reactive species that undergoes polymerisation to form the ICP. In particular, selected monomer(s) reacts with and is oxidised by a chemical oxidant (which is itself reduced) to yield a reactive species that propagates polymerisation and formation of polymer having cationic character. In order to form the ICP, at the time of polymerisation the cationic character of the polymer may be neutralised through association with the dopant (i.e. a suitable anionic species). The dopant may be derived from the chemical oxidant (i.e. a self-doping chemical oxidant) or may be present as a separate distinct species.

Suitable chemical oxidants include metal salts with high oxidizing potential, for example ferric salts such as ferric chloride and ferric p-toluene sulfonate, and corresponding copper(II) salts, vanadium(V) salts, cerium(IV) salts and auric III) salts. Other suitable chemical oxidants include persulfates such as ammonium and potassium persulfate, peroxides such as benzoyl peroxide and hydrogen peroxide, and gases such as fluorene, ozone and chlorine.

Examples of self-doping chemical oxidants include metal (e.g. Fe, Cu, V, Ce, Au) salts of sulfonates, sulfates, chlorides, perchlorates and phosphates.

The amount of chemical oxidant used in the preparation of an ICP will vary with the nature of the monomer and chemical oxidant employed. For example, in vapour phase polymerisation the ratio of oxidant to monomer will progressively change as the oxidant is consumed. In general, the chemical oxidant will be initially applied in an amount ranging from about 0.5 to 4 calculated on a molar ratio basis relative to the monomer.

Whether or not used in association with an oxidising counter cation, suitable dopant anions include those herein defined.

Where appropriate, a mixture of different chemical oxidants and/or dopants may be used.

Chemical oxidative polymerisation may be conducted under acidic conditions. Where the monomers are polymerised under acidic conditions to form the ICP, the acidic conditions may be provided by any suitable means. By “acidic conditions” is meant that the reaction medium in or interface at which the polymerisation occurs as a pH of less than 7. Generally, polymerisation under acidic conditions will be conducted at a pH of less than about 5, for example of less than about 3. The chemical oxidant or dopant may itself provide the acidic conditions or an additional acid such as a mineral acid or a carboxylic acid may be employed.

Depending upon the mode of chemical oxidative polymerisation, the monomers being polymerised may be utilised in the form of a vapour phase (i.e. vapour phase polymerisation) or be present and polymerised in a liquid reaction medium (i.e. bulk polymerisation).

When present and polymerised in a liquid reaction medium, the monomer(s) will generally be dissolved in a polar solvent such as water, alcohol (typically having up to 4 carbon atoms and preferably a primary alcohol with 2-4 carbon atoms) or acetonitrile, that has the capacity to dissolve other reaction components as well as the monomer.

Apart from those outlined above, additional reaction components in the liquid reaction medium may include surfactants and dispersants required to stabilise the reaction mixture against crystallisation or precipitation. Examples of suitable materials for this purpose include polyurethane diol, polypropylene glycol and proprietary surfactant formulations such as Teric BL8 (C12 ethoxylated fatty acid alcohol, Huntsman) and Glysolv (1-methoxy 2-propanol, Huntsman). These materials may be used either neat or as a 5% solution in alcohol, the amount normally used being about 10 wt % of the dry mass of the chemical oxidant employed.

Acids or bases may also be included in the liquid reaction medium and are used to optionally protonate the final ICP for the purpose of increasing conductivity (e.g. mineral acids such as HCl or H₂SO₄) or to retard polymerisation and suppress side reactions (e.g. bases such as pyridine).

Where the ICP is prepared by vapour phase polymerisation, the selected monomer(s) may be used neat, with the optional application of heat or agitation to increase vapour concentration and hence the rate of reaction.

Generally, reagents for a given polymerisation are selected by first having regard to the nature of the ICP that is to be formed. This will in turn of course determine the monomer(s) that is to be used. Other reagents for the polymerisation may then be chosen. Chemical oxidants are typically chosen on the basis of their ability to polymerise the appropriate monomer(s) and their potential for self-doping. The reagents of the polymerisation will of course also be selected such that they afford an ICP that, during operation of the cell, reduces an oxidised species of the selected redox couple.

Having selected the reagents to form the ICP, the chemical oxidant may then be exposed to monomer(s) that is in the vapour phase such that it undergoes vapour phase polymerisation to form the polymer. Alternatively, the chemical oxidant may be exposed to the monomers) in liquid form such that it undergoes bulk polymerisation to form the polymer. Volatile liquid remaining will typically be removed, for example by evaporation or solvent washing, to leave behind the ICP. Vapour phase and bulk polymerisation reagents, apparatus and techniques, known to those skilled in the art may be conveniently used to prepare the ICP's for use in accordance with the invention.

When conducting the polymerisation by vapour phase polymerisation, the chemical oxidant may be applied to the surface of a substrate, for example a substrate having at its surface a layer comprising the metallic nickel and the coated substrate exposed to monomer(s) in the vapour phase. The chemical oxidant may be conveniently applied to the substrate surface by first forming a liquid composition of the chemical oxidant and applying this liquid composition to the surface of the substrate. The liquid composition may be provided by combining the chemical oxidant in one or more suitable solvents. The resulting liquid composition may be applied to the surface of the substrate by any suitable means, for example by spraying, a coatings applicator, printing equipment/technique such as ink jet printers, screen printing, flexographic printing, and combinations thereof.

Multiple layers of the chemical oxidant may be applied to increase the overall thickness of the chemical oxidant coating. Increasing in the thickness of the chemical oxidant coating can promote a corresponding increase in the thickness of the subsequently applied ICP coating.

After the chemical oxidant is applied to the surface of the substrate, any solvent (if present) is generally evaporated prior to performing the polymerisation. For example, the coated substrate may be subjected to elevated temperatures for sufficient time to remove any solvent from the substrate surface. The coated substrate can then be exposed to monomer vapour for a sufficient time at a suitable temperature so as to form the ICP on the coated region(s) of the substrate. It may be necessary to carry out the ICP polymerisation at an elevated temperature to increase the rate of reaction. Further, it may be necessary to separately evaporate the monomer in an enclosed vessel and transport the vapour in an inert gas stream, composed primarily of argon and/or nitrogen, to a reaction vessel in which the oxidant-coated substrate has been placed. At the conclusion of the polymerisation procedure, the ICP-coated substrate will generally be washed free of unreacted oxidant and/or monomer using a polar solvent(s) such as water or ethanol. The ICP-coated substrate will then generally be air dried prior to use.

When performing the polymerisation by bulk polymerisation, a mixture of the chemical oxidant and the monomer(s) may be applied to the surface of a substrate, for example a Substrate having at its surface a layer comprising the metallic nickel to subsequently undergo polymerisation. The chemical oxidant and monomer(s) may be conveniently applied to the substrate surface by first forming a liquid composition comprising these components, and applying this composition to the surface of the substrate. A liquid composition may be provided by combining the chemical oxidant and the monomer(s) in one or more suitable solvents. The resulting liquid composition may be applied to the surface of the substrate by any suitable means, such as those discussed above in respect of the vapour phase polymerisation technique. Volatile liquid remaining will typically be removed, for example by evaporation, to leave behind the ICP.

When performing the polymerisation by bulk polymerisation, it may be desirable to delay polymerisation of the monomer(s) and thereby extend the time available to apply the chemical oxidant/monomer composition before polymerisation takes place. This might be achieved by including in the composition a polymerisation retardant. The polymerisation retardant might function by temporarily deactivating the chemical oxidant. For example, the applied composition might further comprise a volatile polymerisation retardant such as a volatile base that can complex with and render the chemical oxidant temporarily ineffective. Upon application of the chemical oxidant/monomer(s) composition to the surface of the substrate, the base can evaporate thereby reactivating the chemical oxidant which can in turn react with the monomer(s) and promote the polymerisation thereof. An example of a suitable volatile polymerisation retardant includes, but is not limited to, optionally substituted pyridine. Further detail in relation to the use of an optionally substituted pyridine in this manner is described in WO 2005/103109.

The polymerisation retardant may also be in the form of a polyurethane resin. In that case, without wishing to be limited by theory, the resin is believed to provide amine functionality that can complex with and render the chemical oxidant temporarily ineffective. Upon application of the chemical oxidant/monomer(s) composition to the surface of the substrate, reactivation of the chemical oxidant may be achieved simply by heating the applied composition.

In addition to functioning as a polymerisation retardant, it has also been found that use of optionally substituted pyridine as a reagent during chemical oxidative polymerisation can enhance the conductivity of the resulting ICP. Without wishing to be limited by theory, it is believed that the optionally substituted pyridine functions during polymerisation to suppress undesirable side reactions of monomer polymerisation during formation of the ICP that would otherwise result in ring cleavage and consequent reductions in electrical conductivity. Other compounds that have been found to impart a similar effect include urethanes with lone pair electrons that act as a Lewis base such as 2-oxazolidinone, 3-methyl-2-oxazolidinone, N-ethylurethane, 2-hydroxyethyl N-methylcarbamate and polyurethane diol. Such urethanes are conveniently referred to herein as Lewis basic urethanes.

In one embodiment of the invention, the ICP is prepared by electrochemical polymerisation.

In a further embodiment, the ICP is prepared by vapour phase polymerisation. In such an embodiment, a chemical oxidant may be applied on to a surface layer comprising the metallic nickel, and the surface applied with chemical oxidant exposed to one or more monomers in the vapour phase so as to form the ICP on that surface.

In another embodiment, the ICP is formed by bulk polymerisation. In such an embodiment, a composition comprising a chemical oxidant and one or more monomers may be applied to a surface layer comprising the metallic nickel, and the one or more monomers polymerised at that surface to form the ICP. The chemical oxidant and one or more monomer composition applied to the surface may further comprise a polymerisation retardant.

In yet a further embodiment, polymerisation of the one or more monomers to form the ICP may be conducted in the presence of optionally substituted pyridine or a Lewis basic urethane.

By the polymerisation being conducted “in the presence of” a compound such as optionally substituted pyridine, a Lewis basic urethane, or a chemical oxidant is meant that the compound can interact on a molecular level with monomer as it is polymerised to form the ICP.

Other reagents that may be used in preparing the ICP by chemical oxidated polymerisation include a reagent to suppress crystallisation or precipitation of the selected chemical oxidant upon drying of the liquid composition applied to the substrate. In particular, crystallisation or precipitation of the chemical oxidant in the liquid upon drying may result in a relatively non-uniform distribution of the chemical oxidant throughout the composition or on the surface of the substrate. Suitable crystallisation or precipitation suppressants may include polyurethane diol, polypropylene glycol, surfactant formulations such as Teric and BL8 (C12 ethoxylated fatty acid alcohol, Huntsman) and Glysolv (1-methoxy-2-propynol, Huntsman, or combinations thereof.

Further reagents that may be employed in the chemical oxidation polymerisation to form the ICP include, those that can modify the chemical and/or physical properties (e.g. uniformity and elasticity) of the resulting ICP. Such reagents may include polyurethane resin, which may also serve as a polymerisation retardant if required. The molecular weight of the polyurethane resin may be varied to assist with the means of application of the chemical oxidant or chemical oxidant/monomer composition to a given substrate. For example, a low molecular weight resin may assist with providing a composition that has suitable viscosity and elastomeric properties for ink jet printing, whereas a higher molecular weight polyurethane resin may be required to increase the viscosity of the composition for screen printing.

Other reagents such as polyethylene glycol may be employed in the chemical oxidation polymerisation to form the ICP to enhance the smoothness and conductivity of the ICP by promoting an advantageous distribution of polymer domains within the ICP.

The ICP may of course also be first prepared by a given polymerisation technique and then subsequently (a) applied to a surface layer comprising the metallic nickel, or (b) interspersed with the metallic nickel to form a blend thereof. For example, the ICP may be prepared by bulk polymerisation so as to form a dispersion of the polymer in a liquid, and the resulting ICP dispersion (a) applied to a surface layer comprising the metallic nickel, or (b) interspersed with the metallic nickel to form a blend thereof.

There are various ways in which a cathode in accordance with the invention may be constructed. Irrespective of the way in which the cathode is constructed, it must of course be capable of functioning as a cathode within a DSSC. In particular, the cathode comprises an ICP and the metallic nickel, and functions from a practical point of view in a similar manner to conventional cathodes used in conventional DSSC's. Importantly, the ICP of the cathode is of a type that, during operation of the cell, reduces an oxidised species of the redox couple.

The manner in which the cathode is constructed will in part depend upon the form and method of preparation of the ICP and the metallic nickel.

Thus, in one embodiment the cathode comprises the metallic nickel and the ICP interspersed and present as a blend. In that case, the cathode may be constructed using a dispersion of the metallic nickel and a dispersion of the ICP. For example, a liquid dispersion of an ICP may be blended with a liquid dispersion of the metallic nickel, and the resulting dispersion blend used to prepare the cathode. In particular, the dispersion blend used will comprise a liquid phase that can be removed, for example by evaporation, to leave behind a solid intimate blend of the ICP and the metallic nickel. The cathode may be conveniently prepared using this approach by applying the dispersion blend onto a suitable substrate, or by introducing the dispersion blend into a suitable mold.

In a further embodiment, the cathode comprises a layer comprising the ICP that is located on a layer comprising the metallic nickel. For convenience, a cathode according to the invention provided in this form may herein be referred to as a “bi-layered cathode”. According to such an embodiment, a layer comprising the metallic nickel may be formed in a number of ways. For example, the layer may be formed by applying a dispersion comprising the metallic nickel onto a substrate or by introducing a dispersion comprising the metallic nickel into in a suitable mold.

The layer comprising the metallic nickel in the bi-layered cathode may also be formed by a metal depositing technique such as electroplating. Forming the layer by electroplating will generally utilise a suitable electrochemical cell comprising a substrate to be plated (that functions as a cathode in the plating cell), an anode (often comprised of the metal to be plated on the substrate), a suitable soluble salt and solvent system together with a direct current electrical power supply. Electroplating may be carried out under systematic electrical conditions of current and/or voltage under chosen conditions of time, temperature and pH.

Other metal deposition techniques include evaporation or sputtering, in which a source metal is heated in a vacuum to boil off vapour particles that travel to the substrate where they deposit as a film. A further technique is electroless plating, which is an auto-catalytic chemical technique that relies on the presence of a reducing agent, for example sodium hypophosphite, to reduce metal ions and deposit the metal on the substrate.

The layer comprising the metallic nickel in the bi-layered cathode may also be derived from a pre-formed metal foil on to which the ICP is applied. The foil may be first applied onto a substrate and the ICP deposited on to the foil layer of the now foil coated substrate. Such foils can be readily prepared by rolling metal ingots of the required composition.

Where the metallic nickel is provided in the form of a separate layer to the ICP, it will generally be desirable for that nickel containing layer to have a surface roughness that avoids contact with the anode when assembled as part of a DSSC. A cathode that is provided with an overly rough nickel surface layer can result in contact between the nickel and anode in an assembled DSSC and cause a short circuit. Spacers are generally used in DSSC's to prevent contact between the cathode and anode. However, using a lager spacer to compensate for a rough nickel surface layer will inturn require the use of more electrolyte to fill the increased gap between the anode and cathode. As electrolyte can be expensive and can introduce diffusion limitations into the cell, it is desirable to minimise the gap between the cathode and anode in a DSSC.

Spacers typically used in DSSC's are either 25 micron or 60 micron thickness. A spacer of 25 micron thickness is often preferable as the cell will require less electrolyte, which in turn reduces cost and provides less resistance and diffusion limitation, the effect of which imparts improved efficiency.

Where the DSSC comprises a 60 micron spacer, the nickel layer preferably has a surface roughness of less than 30 microns, or less than 25 microns. Where the DSSC comprises a 25 micron spacer, the nickel layer preferably has a surface roughness of less than 15 microns, or less than 10 microns.

By “surface roughness” is meant a measure of distance between the highest peaks and the lowest troughs on the nickel surface layer profile as determined using a Dektak 6M Stylus profiler (Veeco, USA).

A layer comprising the ICP in a bi-layered cathode may also be formed in a number of ways. For example, a layer comprising the ICP may be formed by applying a dispersion thereof onto a layer comprising the metallic nickel. Application of the dispersion may be achieved using a printing technique as herein described.

Alternative approaches for forming the layer comprising the ICP of the bi-layered cathode include using electrochemical and chemical oxidative polymerisation.

The process of forming the layer comprising the ICP by electrochemical polymerisation will typically involve using a three electrode electrochemical cell, where at least a layer comprising the nickel is used as the working electrode, comprising an electrolyte/solvent containing monomer that is to be polymerised and form the ICP. The solvent can be selected according to the solubility of the monomer. By applying a constant or alternating current or voltage, in the voltage range where the monomer will polymerise, the working electrode will be coated with the ICP. The thickness of the coating can be controlled by the polymerisation time.

Where the layer comprising the ICP is prepared by chemical oxidative polymerisation, the polymerisation may be conducted as a bulk or vapour phase polymerisation as described herein.

A bi-layered cathode in accordance, with the invention may be constructed using any suitable combination of techniques described above for preparing layers comprising the metallic nickel and the ICP.

When constructing the bi-layered cathode, the layer comprising the ICP will generally be applied directly onto the layer comprising the metallic nickel (i.e. there will be no interposing layer in between the layer comprising the ICP and the layer comprising the metallic nickel).

Those skilled in the art will appreciate that in order for the bi-layered cathode to function in the DSSC, it will be constructed so as to ensure current can flow through the cathode layers.

In one embodiment, the cathode is constructed such that a layer comprising the ICP is formed on a layer comprising the metallic nickel, wherein the layer comprising the metallic nickel is formed from a dispersion comprising the metallic nickel, and wherein the layer comprising the ICP is formed by chemical oxidative polymerisation, preferably vapour phase chemical oxidative polymerisation.

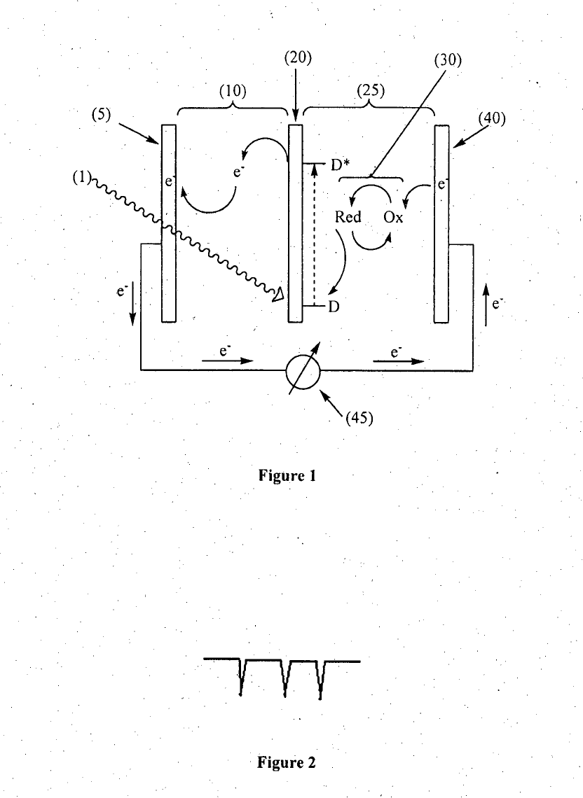

A cathode in accordance with the invention may be represented as the cathode (40) illustrated in FIG. 1. The cathode (40) may therefore comprise the metallic nickel and the ICP interspersed as a blend. The cathode (40) may also comprise a layer comprising the ICP located on a layer comprising the metallic nickel. In that case, the layer comprising the ICP will of course be orientated in a way such that during operation of the cell it can reduce an oxidised species of the redox couple (30). The cathode (40) may comprise a substrate (not shown) that assists with structurally supporting the ICP and the metallic nickel. Suitable substrates include those described herein.

Advantageously, the metallic nickel and the ICP used in accordance with the invention can be readily applied to a flexible substrate, for example by roll-to-roll processing, thereby having the potential to simplify manufacturing cost and also present new applications for DSSC technology. Furthermore, some or the entire cathode may be constructed using printing techniques, thereby simplifying and reducing cost of manufacture.

A more specific example of preparing a cathode in accordance with the invention might include forming a first layer comprising the metallic nickel on a polyester substrate and then applying a layer comprising the ICP on the layer comprising the metallic nickel. For example, a dispersion comprising metallic nickel particles may be applied using a casting technique onto the surface of a polymer (e.g. polyethylene terephthalate (PET)) film to which had a previously been applied a 2 cm² adhesive polymer mask. After the cast dispersion has dried, the mask can be peeled off to leave behind a film comprising metallic nickel particles dispersed within a polymer binder such as an acrylic resin. A solution comprising a chemical oxidant (e.g. Fe (III)-p-toluenesulfonate), pyridine, and a solvent (e.g. butanol) can be applied to the surface of the layer comprising metallic nickel particles. The applied solution can then be dried to afford a self doping chemical oxidant layer on the layer. The resulting self doping chemical oxidant coated layer may then be exposed to suitable monomer in the vapour phase so as to form ICP on the layer by vapour phase polymerisation. The resulting cathode may be washed in a suitable solvent such as ethanol and dried for subsequent use in a DSSC of otherwise standard design and construction.

Those skilled in the art will appreciate the type of components that are employed in conventional DSSC's. With reference to the features of the DSSC schematically illustrated in FIG. 1:

### Transparent Anode (5)

Transparent anodes used in DSSC's are typically constructed of fluorine tin oxide or indium tin oxide coatings on glass or transparent flexible plastics such as PET, PEN or PSU. However, other transparent coatings of conductive materials are now being developed, such as graphene and carbon nanotubes, alone or in combination, although improvements in conductivity will be required before these alternatives become commercially important.

### Semi-Conductor (10)

Examples of semi-conductors used in conventional DSSC's include titanium dioxide (TiO₂), zinc oxide (ZnO) and niobium oxide (Nb₂O₅).

### Photosensitive Dye (20)

Numerous types of photosensitive dyes are known. Two important categories are ‘organic’ dyes and porphyrin dyes, but ruthenium metal complexes are the most common, such as ruthenium-polypyridine dye or triscarboxy-ruthenium terpyridine dye. Other alternatives include 1-ethyl-3 methylimidazolium tetrocyanoborate [EMIB(CN)₄] or copper-diselenium [Cu(In,GA)Se₂].

As used herein, the term “alkyl”, used either alone or in compound words denotes straight chain, branched or cyclic alkyl, preferably C₁₋₂₀ alkyl, e.g. C₁₋₁₀ or C₁₋₆. Examples of straight chain and branched alkyl include methyl, ethyl, n-propyl, isopropyl, n-butyl, sec-butyl, t-butyl, n-pentyl, 1,2-dimethylpropyl, 1,1-dimethyl-propyl, hexyl, 4-methylpentyl, 1-methylpentyl, 2-methylpentyl, 3-methylpentyl, 1,1-dimethylbutyl, 2,2-dimethylbutyl, 3,3-dimethylbutyl, 1,2-dimethylbutyl, 1,3-dimethylbutyl, 1,2,2-trimethylpropyl, 1,1,2-trimethylpropyl, heptyl, 5-methylhexyl, 1-methylhexyl, 2,2-dimethylpentyl, 3,3-dimethylpentyl, 4,4-dimethylpentyl, 1,2-dimethylpentyl, 1,3-dimethylpentyl, 1,4-dimethyl-pentyl, 1,2,3-trimethylbutyl, 1,1,2-trimethylbutyl, 1,1,3-trimethylbutyl, octyl, 6-methylheptyl, 1-methylheptyl, 1,1,3,3-tetramethylbutyl, nonyl, 1-, 2-, 3-, 4-, 5-, 6- or 7-methyloctyl, 1-, 2-, 3-, 4- or 5-ethylheptyl, 1-, 2- or 3-propylhexyl, decyl, 1-, 2-, 3-, 4-, 5-, 6-, 7- and 8-methylnonyl, 1-, 2-, 3-, 4-, 5- or 6-ethyloctyl, 1-, 2-, 3- or 4-propylheptyl, undecyl, 1-, 2-, 3-, 4-, 5-, 6-, 7-, 8- or 9-methyldecyl, 1-, 2-, 3-, 4-, 5-, 6- or 7-ethylnonyl, 1-, 2-, 3-, 4- or 5-propyloctyl, 1-, 2- or 3-butylheptyl, 1-pentylhexyl, dodecyl, 1-, 2-, 3-, 4-, 5-, 6-, 7-, 8-, 9- or 10-methylundecyl, 1-, 2-, 3-, 4-, 5-, 6-, 7- or 8-ethyldecyl, 1-, 2-, 3-, 4-, 5- or 6-propylnonyl, 1-, 2-, 3- or 4-butyloctyl, 1-2-pentylheptyl and the like. Examples of cyclic alkyl include mono- or polycyclic alkyl groups such as cyclopropyl, cyclobutyl, cyclopentyl, cyclohexyl, cycloheptyl, cyclooctyl, cyclononyl, cyclodecyl and the like. Where an alkyl group is referred to generally as “propyl”, butyl” etc, it will be understood that this can refer to any of straight, branched and cyclic isomers where appropriate. An alkyl group may be optionally substituted by one or more optional substituents as herein defined.

As used herein, the term “aryl” denotes any of single, polynuclear, conjugated and fused residues of aromatic hydrocarbon ring systems (e.g. C₆-C₂₄ aryl). Examples of aryl include phenyl, biphenyl, terphenyl, quaterphenyl, naphthyl, tetrahydronaphthyl, anthracenyl, dihydroanthracenyl, benzanthracenyl, dibenzanthracenyl, phenanthrenyl, fluorenyl, pyrenyl, idenyl, azulenyl, chrysenyl. Preferred aryl includes phenyl and naphthyl. An aryl group may be optionally substituted by one or more optional substituents as herein defined.

Terms written as, for example, “[group]oxy” are intended to denote a particular group when linked by oxygen. For example, the terms “alkoxy” or “alkyloxy”, “alkenoxy” or “alkenyloxy”, “alkynoxy” or alkynyloxy”, “aryloxy” and “acyloxy”, respectively, denote alkyl, alkenyl, alkynyl, aryl and acyl groups as defined herein when linked by oxygen. Thus, terms written as “[group]thio” refer to a particular group when linked by sulphur. For example, the terms “alkylthio”, “alkenylthio”, alkynylthio” and “arylthio”, respectively, denote alkyl, alkenyl, alkynyl, aryl groups as defined herein when linked by sulfur. Similarly, terms written as “[group A][group B]” refer to group A when linked by a divalent form of group B. For example, “[group A][alkyl]” refers to a particular group A (such as hydroxy, amino, etc.) when linked by divalent alkyl, i.e. alkylene (e.g. hydroxyethyl is intended to denote HO—CH₂—CH—). Thus, the term “arylalkyl” is intended to mean an aryl group when linked by a divalent alkyl group. For example, an arylalkyl group includes a benzyl group (i.e. (C₆H₅)CH₂—).

As used herein the term “aromatic heterocyclic compound” is intended to include any monocyclic, polycyclic or fused aromatic organic compound in which one or more carbon atoms are replaced by a heteroatom and which are capable of undergoing oxidative polymerisation to form a polymer backbone having an extended conjugated system. Preferred aromatic heterocyclic compounds are five or six membered ring systems. Suitable heteroatoms include O, N, S, P, and Se, particularly O, N and S. Where two or more carbon atoms are replaced, this may be by two or more of the same heteroatom or by different heteroatoms. Suitable examples of aromatic heterocyclic compounds include, but are not limited to, pyridine, pyrrole, thiophene, furan, indole, carbazole, 3,4-ethylenedioxythiophene.

As used herein, the term “optionally substituted” [group] is intended to mean that the [group] may or may not be substituted with one, two, three or more of organic and inorganic groups, including those selected from: sulphonate, carboxylate, phosphonate, nitrate, alkoxy (such as a methoxy, and ring-forming alkoxy groups such as alkylene dioxy groups, such as ethylenedioxy or propylenedioxy groups), alkyl, alkenyl, alkynyl, aryl, arylalkyl, halo, haloalkyl, haloalkenyl, haloalkynyl, haloaryl, hydroxy, alkoxy, alkenyloxy, aryloxy, benzyloxy, haloalkoxy, haloalkenyloxy, haloaryloxy, nitro, nitroalkyl, nitroalkenyl, nitroalkynyl, nitroaryl, nitroheterocyclyl, amino, alkylamino, dialkylamino, alkenylamino, alkynylamino, arylamino, diarylamino, benzylamino, dibenzylamino, acyl, alkenylacyl, alkynylacyl, arylacyl, acylamino, diacylamino, acyloxy, alkylsulphonyloxy, arylsulphenyloxy, heterocyclyl, heterocycloxy, heterocyclamino, haloheterocyclyl, alkylsulphenyl, arylsulphenyl, carboalkoxy, carboaryloxy, mercapto, alkylthio, benzylthio and acylthio, and combinations of any of these groups.

As used herein, the term “alkenyl” denotes groups formed from straight chain, branched or cyclic hydrocarbon residues containing at least one carbon to carbon double bond including ethylenically mono-, di- or polyunsaturated alkyl or cycloalkyl groups as previously defined, preferably C₂₋₂₀ alkenyl (e.g. C₂₋₁₀ or C₂₋₆). Examples of alkenyl include vinyl, allyl, 1-methylvinyl, butenyl, iso-butenyl, 3-methyl-2-butenyl, 1-pentenyl, cyclopentenyl, 1-methyl-cyclopentenyl, 1-hexenyl, 3-hexenyl, cyclohexenyl, 1-heptenyl, 3-heptenyl, 1-octenyl, cyclooctenyl, 1-nonenyl, 2-nonenyl, 3-nonenyl, 1-decenyl, 3-decenyl, 1,3-butadienyl, 1,4-pentadienyl, 1,3-cyclopentadienyl, 1,3-hexadienyl, 1,4-hexadienyl, 1,3-cyclohexadienyl, 1,4-cyclohexadienyl, 1,3-cycloheptadienyl, 1,3,5-cycloheptatrienyl and 1,3,5,7-cyclooctatetraenyl. An alkenyl group may be optionally substituted by one or more optional substituents as herein defined.

As used herein, the term “alkynyl” denotes groups formed from straight chain, branched or cyclic hydrocarbon residues containing at least one carbon-carbon triple bond including ethylenically mono-, di- or polyunsaturated alkyl or cycloalkyl groups as previously defined. Unless the number of carbon atoms is specified the term preferably refers to C₂₋₂₀ alkynyl (e.g. C₂₋₁₀ or C₂₋₆). Examples include ethynyl, 1-propynyl, 2-propynyl, and butynyl isomers, and pentynyl isomers. An alkynyl group may be optionally substituted by one or more optional substituents as herein defined.

As used herein, the term “halogen” (“halo”) denotes fluorine, chlorine, bromine or iodine (fluoro, chloro, bromo or iodo). Preferred halogens are chlorine, bromine or iodine.

As used herein, the term “carbocyclyl” includes any of non-aromatic monocyclic, polycyclic, fused or conjugated hydrocarbon residues, preferably C₃₋₂₀ (e.g. C₃₋₁₀ or C₃₋₈). The rings may be saturated, e.g. cycloalkyl, or may possess one or more double bonds (cycloalkenyl) and/or one or more triple bonds (cycloalkynyl). Particularly preferred carbocyclyl moieties are 5-6-membered or 9-10 membered ring systems. Suitable examples include cyclopropyl, cyclobutyl, cyclopentyl, cyclohexyl, cycloheptyl, cyclooctyl, cyclononyl, cyclodecyl, cyclopentenyl, cyclohexenyl, cyclooctenyl, cyclopentadienyl, cyclohexadienyl, cyclooctatetraenyl, indanyl, decalinyl and indenyl.

As used herein, the term “heterocyclyl” when used alone or in compound words includes any of monocyclic, polycyclic, fused or conjugated hydrocarbon residues, preferably C₃₋₂₀ (e.g. C₃₋₁₀ or C₃₋₈) wherein one or more carbon atoms are replaced by a heteroatom so as to provide a non-aromatic residue. Suitable heteroatoms include O, N, S, P and Se, particularly O, N and S. Where two or more carbon atoms are replaced, this may be by two or more of the same heteroatom or by different heteroatoms. The heterocyclyl group may be saturated or partially unsaturated, i.e. possess one or more double bonds. Particularly preferred heterocyclyl are 5-6 and 9-10 membered heterocyclyl. Suitable examples of heterocyclyl groups may include azridinyl, oxiranyl, thiiranyl, azetidinyl, oxetanyl, thietanyl, 2H-pyrrolyl, pyrrolidinyl, pyrrolinyl, piperidyl, piperazinyl, morpholinyl, indolinyl, imidazolidinyl, imidazolinyl, pyrazolidinyl, thiomorpholinyl, dioxanyl, tetrahydrofuranyl, tetrahydropyranyl, tetrahydropyrrolyl, tetrahydrothiophenyl, pyrazolinyl, dioxalanyl, thiazolidinyl, isoxazolidinyl, dihydropyranyl, oxazinyl, thiazinyl, thiomorpholinyl, oxathianyl, dithianyl, trioxanyl, thiadiazinyl, dithiazinyl, trithianyl, azepinyl, oxepinyl, thiepinyl, indenyl, indanyl, 3H-indolyl, isoindolinyl, 4H-quinolazinyl, chromenyl, chromanyl, isochromanyl, pyranyl and dihydropyranyl.

As used herein, the term “acyl” either alone or in compound words denotes a group containing the moiety C═O (and not being a carboxylic acid, ester or amide) Preferred acyl includes C(O)—R, wherein R is hydrogen or an alkyl, alkenyl, alkynyl, aryl, heteroaryl, carbocyclyl, or heterocyclyl residue. Examples of acyl include formyl, straight chain or branched alkanoyl (e.g. C₁₋₂₀) such as, acetyl, propanoyl, butanoyl, 2-methylpropanoyl, pentanoyl, 2,2-dimethylpropanoyl, hexanoyl, heptanoyl, octanoyl, nonanoyl, decanoyl, undecanoyl, dodecanoyl, tridecanoyl, tetradecanoyl, pentadecanoyl, hexadecanoyl, heptadecanoyl, octadecanoyl, nonadecanoyl and icosanoyl; cycloalkylcarbonyl such as cyclopropylcarbonyl cyclobutylcarbonyl, cyclopentylcarbonyl and cyclohexylcarbonyl; aroyl such as benzoyl, toluoyl and naphthoyl; aralkanoyl such as phenylalkanoyl (e.g. phenylacetyl, phenylpropanoyl, phenylbutanoyl, phenylisobutylyl, phenylpentanoyl and phenylhexanoyl) and naphthylalkanoyl (e.g. naphthylacetyl, naphthylpropanoyl and naphthylbutanoyl]; aralkenoyl such as phenylalkenoyl (e.g. phenylpropenoyl, phenylbutenoyl, phenylmethacryloyl, phenylpentenoyl and phenylhexenoyl and naphthylalkenoyl (e.g. naphthylpropenoyl, naphthylbutenoyl and naphthylpentenoyl); aryloxyalkanoyl such as phenoxyacetyl and phenoxypropionyl; arylthiocarbamoyl such as phenylthiocarbamoyl; arylglyoxyloyl such as phenylglyoxyloyl and naphthylglyoxyloyl; arylsulfonyl such as phenylsulfonyl and napthylsulfonyl; heterocycliccarbonyl; heterocyclicalkanoyl such as thienylacetyl, thienylpropanoyl, thienylbutanoyl, thienylpentanoyl, thienylhexanoyl, thiazolylacetyl, thiadiazolylacetyl and tetrazolylacetyl; heterocyclicalkenoyl such as heterocyclicpropenoyl, heterocyclicbutenoyl, heterocyclicpentenoyl and heterocyclichexenoyl; and heterocyclicglyoxyloyl such as thiazolyglyoxyloyl and thienyiglyoxyloyl. The R residue may be optionally substituted as described herein.

As used herein, the term “sulfoxide”, either alone or in a compound word, refers to a group —S(O)R wherein R is selected from hydrogen, alkyl, alkenyl, alkynyl, aryl, heteroaryl, heterocyclyl, carbocyclyl, and arylalkyl. Examples of preferred R include C₁₋₂₀alkyl, phenyl and benzyl.

As used herein, the term “sulfonyl”, either alone or in a compound word, refers to a group S(O)₂—R, wherein R is selected from hydrogen, alkyl, alkenyl, alkynyl, aryl, heteroaryl, heterocyclyl, carbocyclyl and arylalkyl. Examples of preferred R include C₁₋₂₀alkyl, phenyl and benzyl.

As used herein, the term “sulfonamide”, either alone or in a compound word, refers to a group S(O)NRR wherein each R is independently selected from hydrogen, alkyl, alkenyl, alkynyl, aryl, heteroaryl, heterocyclyl, carbocyclyl, and arylalkyl. Examples of preferred R include C₁₋₂₀alkyl, phenyl and benzyl. In a preferred embodiment at least one R is hydrogen. In another form, both R are hydrogen.

As used herein, the term, “amino” is used here in its broadest sense as understood in the art and includes groups of the formula NR^{A}R^{B} wherein R^{A} and R^{B} may be any independently selected from hydrogen, alkyl, alkenyl, alkynyl, aryl, carbocyclyl, heteroaryl, heterocyclyl, arylalkyl, and acyl. R^{A} and R^{B}, together with the nitrogen to which they are attached, may also form a monocyclic, or polycyclic ring system e.g. a 3-10 membered ring, particularly, 5-6 and 9-10 membered systems. Examples of “amino” include NH₂, NHalkyl (e.g. C₁₋₂₀alkyl), NHaryl (e.g. NHphenyl), NHaralkyl (e.g. NHbenzyl), NHacyl (e.g. NHC(O)C₁₋₂₀alkyl, NHC(O)phenyl), Nalkylalkyl (wherein each alkyl, for example C₁₋₂₀, may be the same or different) and 5 or 6 membered rings, optionally containing one or more same or different heteroatoms (e.g. O, N and S).

As used herein, the term “amido” is used here in its broadest sense as understood in the art and includes groups having the formula C(O)NR^{A}R^{B}, wherein R^{A} and R^{B} are as defined as above. Examples of amido include C(O)NH₂, C(O)NHalkyl (e.g. C₁₋₂₀alkyl), C(O)NHaryl (e.g. C(O)NHphenyl), C(O)NHaralkyl (e.g. C(O)NHbenzyl), C(O)NHacyl (e.g. C(O)NHC(O)C₁₋₂₀alkyl, C(O)NHC(O)phenyl), C(O)Nalkylalkyl (wherein each alkyl, for example C₁₋₂₀, may be the same or different) and 5 or 6 membered rings, optionally containing one or more same or different heteroatoms (e.g. O, N and S).

As used herein, the term “carboxy ester” is used here in its broadest sense as understood in the art and includes groups having the formula CO₂R, wherein R may be selected from groups including alkyl, alkenyl, alkynyl, aryl, carbocyclyl, heteroaryl, heterocyclyl, arylalkyl, and acyl. Examples of carboxy ester include CO₂C₁₋₂₀alkyl, CO₂aryl (e.g. CO₂phenyl), CO₂aralkyl (e.g. CO₂ benzyl).

The term “heteroatom” or “hetero” as used herein in its broadest sense refers to any atom other than a carbon atom which may be a member of a cyclic organic group. Particular examples of heteroatoms include nitrogen, oxygen, sulfur, phosphorous, boron, silicon, selenium and tellurium, more particularly nitrogen, oxygen and sulfur.

The invention will now be described with reference to the following non-limiting examples which illustrate some preferred embodiments of the invention. However, it is to be understood that the particularity of the following description is not to supersede the generality of the proceeding description of the invention.

### EXAMPLES

### Example 1

### Coating of Nickel Formulation

Cathodes for dye-sensitised solar cells (DSSCs) were prepared using a two step procedure. First a layer of the MG Chemicals acrylic nickel was applied to a polyester or glass substrate and then a layer of poly(3,4-ethylenedioxythiophene) (abbreviated as PEDOT) was added on top of the nickel.

The nickel coatings were applied using two different methods, employing both a casting and a coating approach. The acrylic nickel suspension (from MG Chemicals, Canada) was drawn down the surface of PET films (DuPont Melinex ST506) that had previously been equipped with a 2 cm² adhesive polymer mask. After drying, the mask was peeled off to reveal a hard film of the acrylic nickel on the substrate surface with the required geometry, typically 15-25 micrometers in thickness. Alternatively, the acrylic nickel suspension (from MG Chemicals, Canada) was applied to the surface of PET films (DuPont Melinex ST506) using a draw down bar coater (RK Print Coat Instruments, UK) and allowed to cure in air for at least 24 hours.

The surface roughness of the coating was determined by taping a small piece of nickel-coated PET onto a glass slide using Scotch Poster Tape (3M, USA) and using a contact profilometer (Dektak 6M Stylus Profiler, Veeco, USA) to obtain a profile of the sample. The instrument's software was then used to determine the distance between the highest peaks and the lowest troughs of the profile, and this was taken as the “maximum roughness” of the sample.

To determine the thickness of the coated nickel formulation, the formulation was also coated onto glass (Monash Glass, Australia) using the draw down bar coater and step heights measured with the contact profilometer.

The surface resistivity of the nickel coating on PET was measured using a four point probe (Jandel Model RM3, UK).

### Results

For the most part, the nickel formulation gave a consistent, even coating on the PET substrate. Some inconsistencies were observed when the container of nickel formulation had been open for some time, i.e. greater than six months, as the formulation's volatile organic solvent evaporated over time, resulting in an increase in viscosity of the formulation. When the formulation became too viscous to give an even coating, it was diluted to a workable consistency using methyl ethyl ketone (MEK) and ethanol.

The mean thickness of the nickel coating on glass was found to be 24 microns, with a standard deviation of 3 microns. Full results can be found in Appendix 1. It was assumed that thickness of the nickel coating on the glass substrate would be the same as the thickness of the coating on PET substrate applied under the same conditions.

The maximum roughness of the nickel coating on PET was found to be 15 microns, i.e. 15 microns between the highest peaks and lowest troughs, with a standard deviation of 2 microns. After successive polishing with 600, 1200 and 2500 grit wet/dry silicon carbide paper, the maximum roughness was reduced to 8 microns, with a standard deviation of 2 microns. The polishing process effectively reduced the peaks on the sample. A schematic of the profile of the polished nickel coating is shown in FIG. 2.

### Example 2

### Polishing the Nickel Coating

After curing for 24 hours, the nickel coating was polished successively with 600, 1200 and 2500 grit wet/dry silicon carbide paper. The polished, coated PET was then rinsed with ethanol and roughness measured using the contact profilometer as detailed above.

The resistance of the coating was measured to be 8 Ohm/sqr after drying.

### Example 3

### Durability Tests of the Nickel Coating in Dssc Electrolytes

1. In order to ascertain durability of the nickel coating in DSSC electrolytes, glass and PET coated with the commercial nickel coating were immersed in a typical ionic liquid based DSSC electrolyte and observed at regular intervals to determine whether or not the coating was durable in the electrolyte solution. The electrolyte used in this study was based on one previously reported in the literature². This solution consisted of 0.14 M guanidine thiocyanate, 0.2 M iodine and 0.5 M 4-tert-butyl pyridine in a 13:7 mixture of PMII and 1-ethyl-3-methylimidazolium thiocyanate (EMINCS).

### Results

After 109 days of immersion in the ionic-liquid-based electrolyte solution, the nickel/acrylic binder coating on both the glass and the PET substrate were still intact.

### Example 4

### Printing of PEDOT:PTS on the Nickel Coated PET

An oxidant for the production of Vapour Pressure Polymerised (VPP) PEDOT:PTS was printed on the polished, rinsed nickel-coated PET using a laboratory scale gravure printer (RK Print Coat Instruments, UK) at speed 4.5. To prepare this oxidant, 0.033 g of polyethylene glycol was dissolved in 0.2 mL deionised water. This solution was then added to 1 mL of Baytron formulation (Fe(III)p-toluenesulfonate in 1-butanol, HC Starck, Germany). Finally, 0.03 g polyurethane diol (88 wt % in water, Aldrich, USA) was added to complete the oxidant solution. A rectangle of dimensions 24 mm×150 mm was printed and the sample immediately transferred to a glass, vapour phase polymerisation (VPP) treatment chamber, and suspended above a few millilitres of EDOT at 55° C. for 45 minutes. The sample was then washed in ethanol and dried in air.

Samples were made with one, two and three layers of PEDOT:PTS on the PET/nickel substrate. These layers were applied by first gravure printing all layers of the oxidant using the gravure proofer and a 250 line per inch printing plate, and then polymerising all the layers at once.

Alternatively, to a solution of the Baytron formulation was added pyridine in a molar ratio of 0.50 relative to the concentration of Fe(III) in the Baytron C-B40. Pyridine acts as a Lewis base, moderating the acidity of the oxidant and preventing ring cleavage and low conductivity of the final PEDOT polymer. The Baytron-pyridine mixed solution was applied with a pipette and allowed to drain, covering the nickel-coated substrate in a thin, uniform layer. The oxidant-coated substrates were dried in an oven at 70° C. for 60 s and then transferred to a glass VPP treatment chamber, in which they were suspended above a pool of EDOT, again at 70° C. in an oven for 30 min. The coated samples were washed twice in ethanol for 10 min and dried in air. After washing the sample was dried and ready to use as a cathode in DSSC.

### Results

Generally, gravure printing the oxidant produced a sharp, defined print on the PET/nickel substrate and an equally defined and uniform area of PEDOT:PTS. The print quality was related to the smoothness of the nickel coating, i.e. the smoother the nickel coating, the higher the print quality. Although further investigations are required, it is expected that smoother nickel coatings would also make the mass of the applied VPP PEDOT:PTS more reproducible.

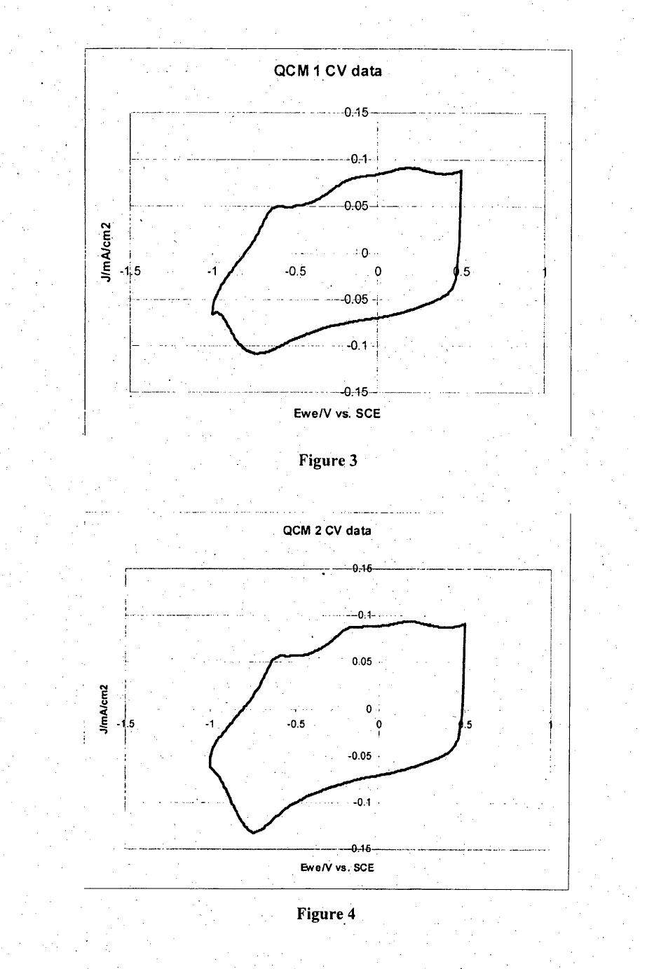

Cyclic voltammetry scans of the PEDOT:PTS quartz crystals, which were used to determine the amount of PEDOT:PTS printed on each sample, are shown in FIGS. 3 and 4.

The amplitude of the scans was recorded at Ewe/V vs. SCE=1 and used to determine the mass of PEDOT:PTS on unknown samples.

To vary the amount of PEDOT:PTS printed on the samples, one, two and three layers of oxidant were printed on the PET/nickel substrate, with vapour phase polymerisation after all layers were printed. It is not yet known if printing multiple layers of PEDOT:PTS affects the morphology and catalytic properties of the material in any way, other than affording a thicker layer of PEDOT:PTS. However, it is known that, unlike platinum, in which catalytic activity occurs only on the surface of, the material, catalytic activity in conducting polymers can occur throughout the material due to their porous structure 5.

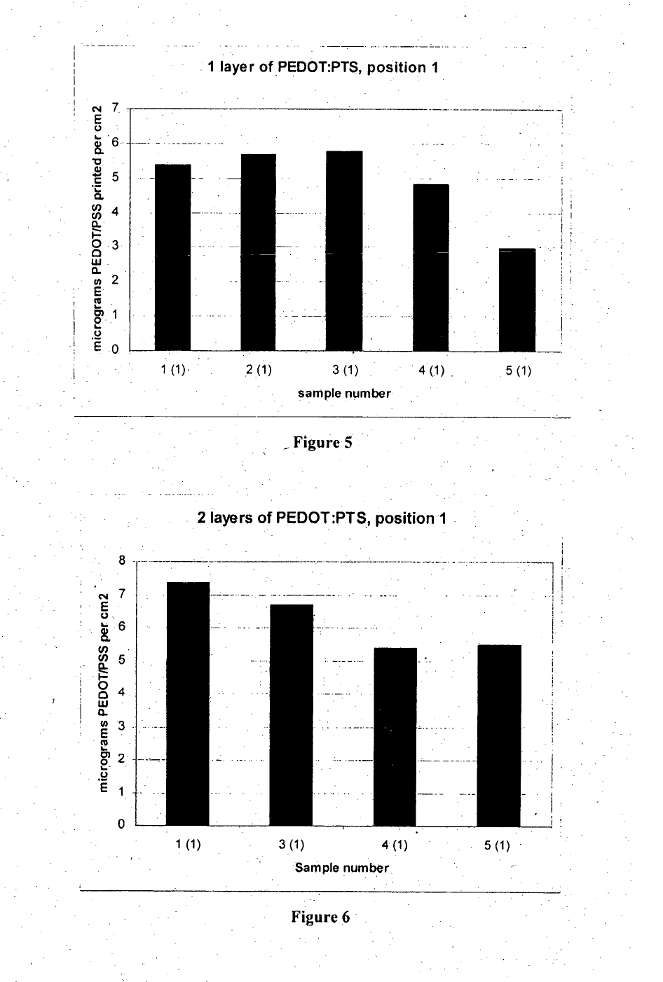

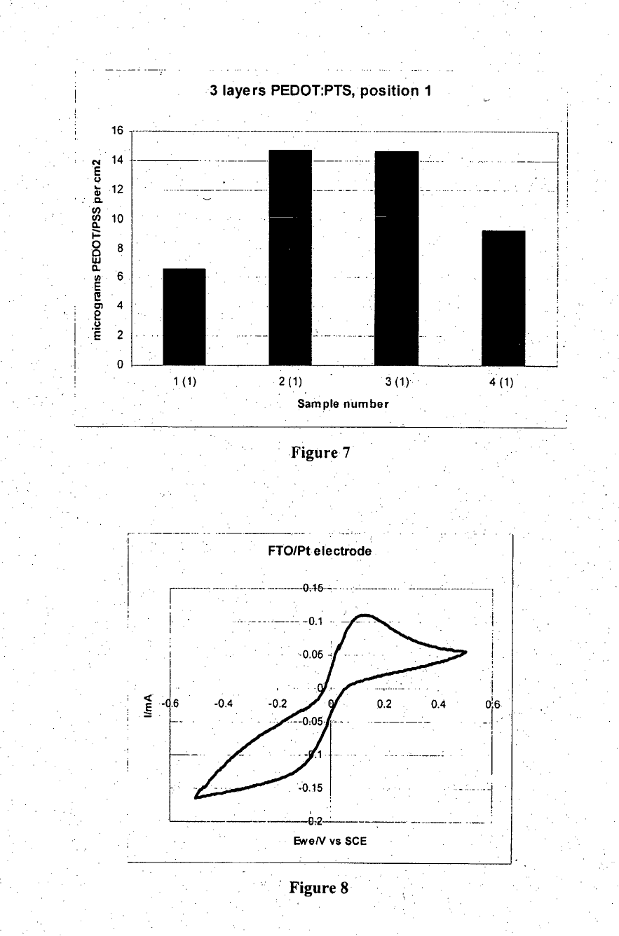

Results of measurements of the mass of VPP PEDOT:PTS deposited on PET/nickel substrates are presented in FIGS. 5-7.

The results show that the amount of PEDOT:PTS deposited on the PET/nickel substrate was not reproducible. When one layer of oxidant was printed, the amount of PEDOT:PTS deposited onto the substrate ranged from 3.0 to 5.8 micrograms per cm². The amount of PEDOT:PTS deposited when two layers of oxidant were printed ranged from 5.4 to 7.4 micrograms. When three layers of oxidant were printed, between 6.6 and 14.7 micrograms were printed.

A number of reasons may be contributing to the lack of reproducibility of the results. The polishing of the samples, which is done by hand, may have varied between samples, affecting the printing of the oxidant. An insufficient amount of EDOT monomer may have been added to the VPP chamber, resulting in all the printed oxidant not reacting to form PEDOT:PTS. In cases of samples being printed with more than one layer of oxidant, the EDOT monomer may have not penetrated the thick oxidant layer, again resulting in unreacted oxidant. Any unreacted EDOT monomer on samples would have been rinsed away during washing of the samples.

### Example 5

### Determining Mass of PEDOT:PTS Printed on Samples

The mass of PEDOT:PTS was determined using a Stanford Research Systems quartz crystal microbalance (QCM 200) (USA). Oxidant for the production of PEDOT:PTS was spin coated using a Laurell spin coater (WS-400B-6NPP/LITE) (USA) onto two quartz crystals and vapour phase polymerised with EDOT monomer. The mass difference of the quartz crystals before and after coating was used to determine the mass of applied PEDOT:PTS. Cyclic voltammetry scans were then taken of the PEDOT:PTS coated quartz crystals and the amplitude of the scan was related to the mass of PEDOT:PTS on the quartz crystal. This data was then used to determine the mass of PEDOT:PTS on PET/nickel/PEDOT:PTS samples.

The mass of PEDOT:PTS was determined at different points of each sample. This is due to the print resulting from the gravure proofer being in a “wedge” shape, with more oxidant being deposited at the beginning of the print than at the end of the print. The printed area was divided into 24 mm×10 mm horizontal sections and the mass of PEDOT:PTS on the first, seventh (i.e. in the centre of the sample) and the last sections was determined.

The electrolyte used for this electrochemical testing was based on an electrolyte used in a study conducted by Wang et al. in 2004². The electrolyte contained 0.2 M iodine (Aldrich, USA), 0.14 M guanidinium thiocyanate (Merck, Germany) and 0.5 M 4-tert-butylpyridine (Aldrich, USA) in a 13:7 volume ratio mixture of 1-methyl-3-propyl imidazolium iodide (Aldrich, USA) and 1-ethyl-3-methyl imidazolium thiocyanate (Aldrich, USA).

### Example 6

### DSSC Construction and Electrochemical Testing of PET/Nickel/PEDOT:PTS Counter Electrode

Electrical impedance spectroscopy and cyclic voltammetry of symmetric cells was conducted to determine electrochemical characteristics of the PET/nickel/PEDOT:PTS counter electrode.

Cells used for this electrochemical testing were symmetric and fabricated using either the alternate PET/nickel/PEDOT:PTS electrode or the standard glass/FTO/platinum electrode. One electrode had a Surlyn spacer melted onto it (Solarnix Meltonix 1170-60) (Switzerland), affording a space of 5 mm×7 mm×60 μm for the electrolyte. A drop of electrolyte was then added to the space, and the second, identical electrode was then clamped on top. Electrical wires were soldered onto these electrodes using an ultrasonic soldering system (USS-9200, MBR Electronics) (Switzerland) and Cerasolver Alloy #143 soldering wire (MBR Electronics) (Switzerland).

The electrolyte used in this electrochemical testing was identical to that used for the cyclic voltammetry scans to determine the amount of PEDOT:PTS printed on each sample.

Selection of electrolytes for use with this counter electrode requires consideration of its durability and roughness profile.

Experiments have shown that the nickel/acrylic binder component of the counter electrode can be dissolved using common organic solvents such as nitriles and alcohols. However, the electrode showed good durability in an ionic liquid electrolyte solution. For this reason, ionic liquid electrolytes have been used in electrochemical testing and the majority of DSSC fabrication.

There is a further advantage to the use of ionic-liquid-based electrolytes in this application. Due to the particular roughness profile of the polished nickel layer (FIG. 2), very low viscosity electrolytes, i.e. organic-solvent-based electrolytes, could potentially leak out of the cell through the channels in the coating. Consequently, a more viscous electrolyte, i.e. an ionic liquid based electrolyte, is preferable.

### Results

Electrochemical testing of PET/nickel/PEDOT:PTS counter electrodes have been conducted using cyclic voltammetry and impedance spectroscopy.

Cyclic voltammetry on symmetric cells fabricated using two identical electrodes was conducted both to observe differences in scans on PET/nickel/PEDOT:PTS compared to scans obtained from traditional glass/FTO/Pt electrodes, and to determine whether or not the gradient of the graph resulting from the scan correlated to the amount of PEDOT:PTS deposited on the PET/nickel substrate.

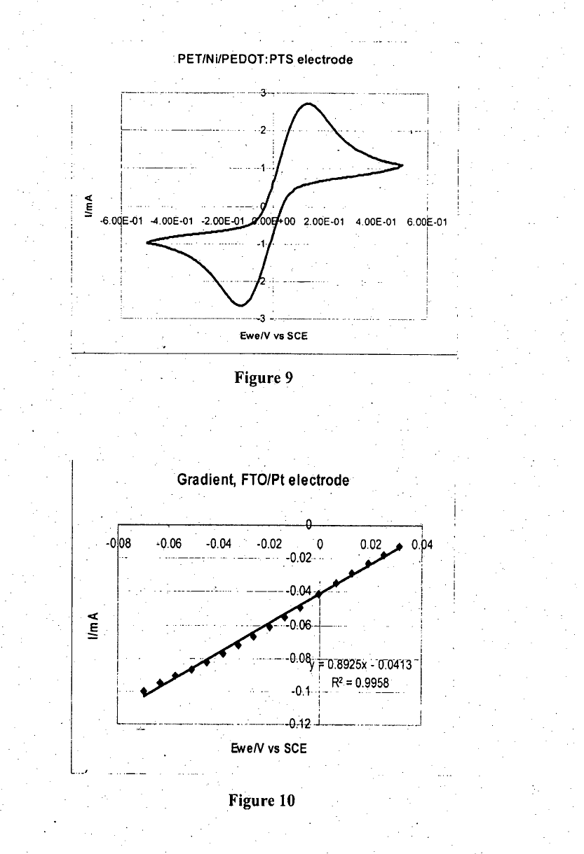

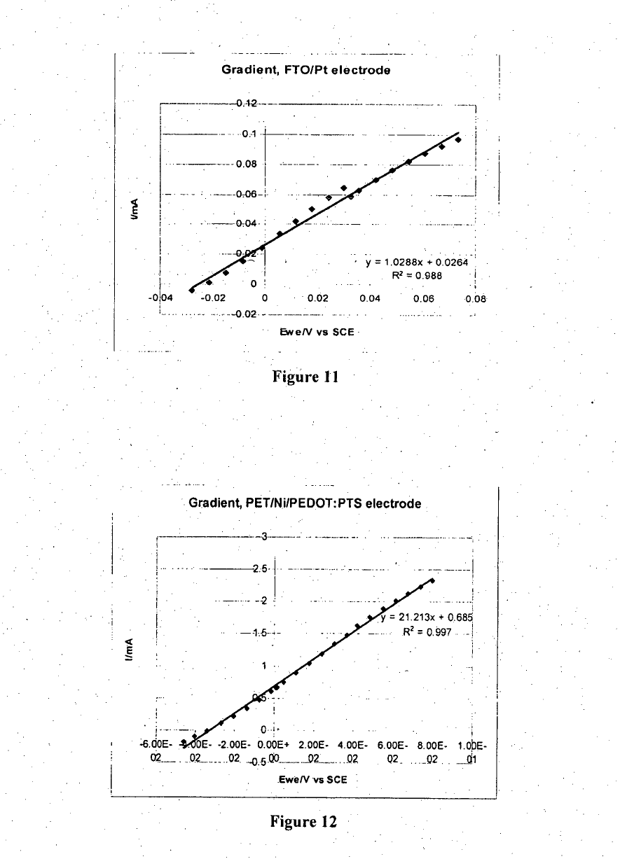

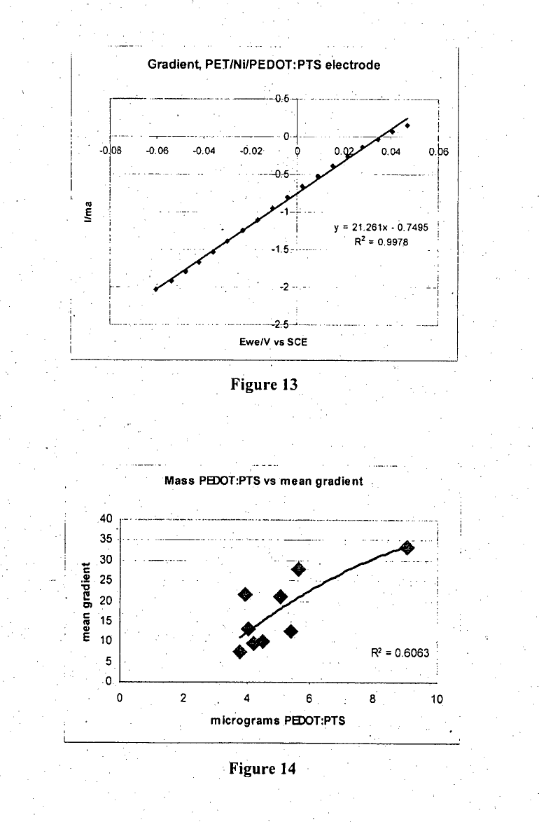

Graphs resulting from these cyclic voltammetry scans are shown below (FIGS. 8 and 9). The gradients of these graphs were determined by graphing the diagonal, vertical lines of each graph separately and taking the gradient from the graph's equation, as shown in FIGS. 10-13. For example, the gradient of the graph in FIG. 10 is 0.89 and the gradient of the graph in FIG. 13 is 21.3

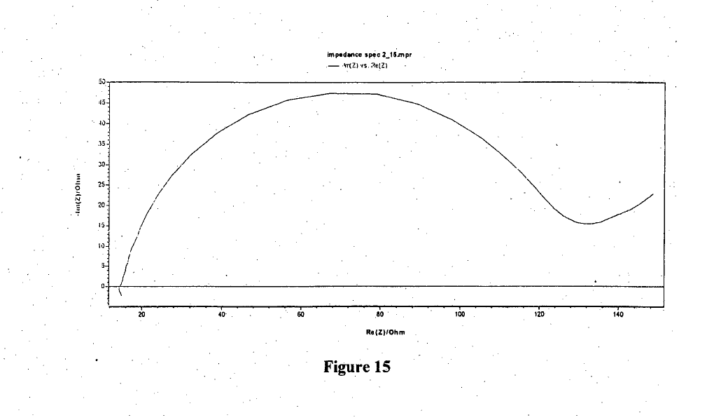

A graph of the correlation between the gradient of the graph resulting from these symmetric cell cyclic voltammetry scans and the amount of PEDOT:PTS printed on each electrode is shown in FIG. 14.

Although there is a general trend in the correlation of the amount of PEDOT:PTS printed on each sample versus the mean gradient of the graph, the correlation coefficient (R²) is only 0.6, indicating that the correlation of these factors is low. This low correlation suggests that there are factors contributing non-constant resistance to the system.

Preliminary electrical impedance spectroscopy has been conducted on the system with the objective of determining the resistance being contributed to the system. A typical electrical impedance scan is shown in FIG. 15.

Analysis of electrical impedance scans of the system have shown that resistance is being contributed from three different sources, these being assumed to be the electrolyte, wires and/or nickel coating, and the PEDOT:PTS coating.

The reference in this specification to any prior publication (or information derived from it), or to any matter which is known, is not, and should not be taken as an acknowledgment or admission or any form of suggestion that that prior publication (or information derived from it) or known matter forms part of the common general knowledge in the field of endeavour to which this specification relates.

Throughout this specification and the claims which follow, unless the context requires otherwise, the word “comprise”, and variations such as “comprises” and “comprising”, will be understood to imply the inclusion of a stated integer or step or group of integers or steps but not the exclusion of any other integer or step or group of integers or steps.

Many modifications will be apparent to those skilled in the art without departing from the scope of the present invention.

### REFERENCES

1. J. M. Pringle, V. Armel and D. R. MacFarlane, Chem. Commun., 46, 5367-5369.
2. P. Wang, S. M. Zakeeruddin, R. Humphry-Baker and M. Gratzel, Chem. Mat., 2004, 16, 2694-2696.
3. P. Wang, S. M. Zakeeruddin and M. Gratzel, in Symposium on Fluorine in Alternative Energy Sources, Elsevier Science Sa, New York, N.Y., 2003, pp. 1241-1245.
4. T. Muto, M. Ikegami and T. Miyasaka, J. Electrochem. Soc., 157, B1195-B1200.

1. A cathode for use in a dye-sensitised solar cell which comprises a redox couple, wherein the cathode comprises:
(a) metallic nickel; and
(b) intrinsically conducting polymer that, during operation of the cell, reduces an oxidised species of the redox couple.

2. The cathode according to claim 1, wherein the intrinsically conducting polymer is interspersed with the metallic nickel so as to form a composite blend.

3. The cathode according to claim 1, wherein a layer comprising the intrinsically conducting polymer is located upon a layer comprising the metallic nickel.

4. The cathode according to claim 3, wherein the layer comprising the metallic nickel consists essentially of nickel.

5. The cathode according to claim 3, wherein the layer comprising the metallic nickel is in the form of metallic nickel particles dispersed within a polymer matrix.

6. The cathode according to claim 1, wherein the cathode further comprises, or is formed on, a substrate.

7. The cathode according to claim 6, wherein the substrate is a flexible polymer suitable for use in roll-to-roll processing.

8. A method of manufacturing a cathode for use in a dye-sensitised solar cell that comprises a redox couple, the method comprising constructing the cathode using:
(a) metallic nickel; and
(b) intrinsically conducting polymer that, during operation of the cell, reduces an oxidised species of the redox couple.

9. The method according to claim 8, wherein the metallic nickel and the intrinsically conducting polymer are provided in the form of a dispersion, and wherein said dispersion is applied to a substrate to form a layer thereon.

10. The method according to claim 8, wherein the metallic nickel is in the form of a dispersion comprising a polymer binder, and wherein said dispersion is applied to a substrate to form a layer thereon.

11. The method according to claim 8, wherein the metallic nickel is applied to a substrate to form a layer thereon using a metal deposition technique selected from electroplating, evaporation, vacuum sputtering, and electroless plating.

12. The method according to claim 10 or wherein a layer comprising the intrinsically conducting polymer is formed on the layer comprising the metallic nickel.

13. The method according to claim 12, wherein the layer comprising the intrinsically conducting polymer is formed using a dispersion comprising the intrinsically conducting polymer.

14. The method according to claim 12, wherein the layer comprising the intrinsically conducting polymer is formed using an electrochemical or chemical oxidative polymerisation technique.

15. The method according to claim 9, wherein application of the metallic nickel or intrinsically conducting polymer to the substrate is conducted using roll-to-roll processing.

16. A dye-sensitised solar cell comprising a cathode and a redox couple, wherein the cathode comprises:
(a) metallic nickel; and
(b) intrinsically conducting polymer that, during operation of the cell, reduces an oxidised species of the redox couple.

17. The dye-sensitised solar cell according to claim 16, wherein the intrinsically conducting polymer is interspersed with the metallic nickel so as to form a composite blend of the intrinsically conducting polymer and the metallic nickel.

18. The dye-sensitised solar cell according to claim 16, wherein a layer comprising the intrinsically conducting polymer is located upon a layer comprising the metallic nickel.
